(19) United States
(12) Patent Application Publication
(10) Pub. No.: US 2025/0160060 A1
(43) Pub. Date: May 15, 2025

(54) LIGHT-EMITTING DIODE COMPRISING NANOHOLES HAVING METAL NANOPARTICLES APPLIED THERETO, AND MANUFACTURING METHOD THEREOF

(71) Applicant: Korea University Research and Business Foundation, Seoul (KR)

(72) Inventors: In Hwan LEE, Seoul (KR); Tae Hwan KIM, Seoul (KR)

(73) Assignee: Korea University Research and Business Foundation, Seoul (KR)

(21) Appl. No.: 18/839,328

(22) PCT Filed: Feb. 18, 2022
(86) PCT No.: PCT/KR2022/002406

§ 371 Date: Aug. 16, 2024

(30) Foreign Application Priority Data
Feb. 16, 2022 (KR) 10-2022-0020230

(51) Int. Cl. H10H 20/819; H10H 20/01; H10H 20/816; H10H 20/825

(52) U.S. Cl. CPC H10H 20/819; H10H 20/01335; H10H 20/816; H10H 20/825

(57) ABSTRACT

A light-emitting device including nanoholes may include a first conductive semiconductor layer, an active layer formed on the first conductive semiconductor layer, a second conductive semiconductor layer formed on the active layer, and nanoholes coated with nanoparticles that cause surface plasmon resonance. The nanoholes may be formed to penetrate the second conductive semiconductor layer and the active layer. Since areas adjacent to the active layer are semi-permanently coated with nanoparticles through nanoholes, the surface plasmon resonance effect may be maximized in the light-emitting device.

### TECHNICAL FIELD

The present invention relates to a light-emitting device to which nanoparticles are applied, and more particularly, to a light-emitting device including nanoholes to which metal nanoparticles are applied and a method of manufacturing the light-emitting device.

### Background Art

The plasmonic effect is a phenomenon in which free electrons in a metal collectively vibrate due to external light, and corresponds to the photo-electronic effect that occurs in metals. This plasmonic effect is caused by a resonance phenomenon in which most of light energy in incident light of a specific wavelength is transferred to free electrons.

In the case of nanoscale metal particles, light absorption occurs when plasmons are coupled with the electric field of light in the visible to near-infrared range, resulting in vivid colors. This phenomenon is called surface plasmon resonance, and surface plasmon resonance can generate locally greatly increased electric fields.

This electric field can be generated when light energy is converted by surface plasmons and accumulated on the surface of metal nanoparticles. In addition, the generation of an electric field may mean that light control is possible in areas smaller than the diffraction limit of light.

Metal nanoparticles have strong and characteristic interactions with electromagnetic waves, such as the surface plasmon resonance phenomenon, thereby enabling amplification and control of the optical absorption band. Accordingly, metal nanoparticles are expected to be applied to various fields such as fluorescence spectroscopy, various types of sensors, and optoelectronic devices.

However, in the case of light-emitting devices according to the related art, the process of semi-permanently coating LEDs with metal nanoparticles is complicated. In addition, there are limits to enhancing the surface plasmon effect with metal nanoparticles.

### DISCLOSURE

### Technical Problem

Therefore, the present invention has been made in view of the above problems, and it is one object of the present invention to provide a light-emitting device including nanoholes coated with nanoparticles and formed deep enough to penetrate an active layer.

It is another object of the present invention to provide a light-emitting device that maximizes the effect of surface plasmon resonance by nanoparticles.

It is yet another object of the present invention to provide a method of manufacturing the light-emitting device including nanoholes.

However, the problems that the present invention aims to solve are not limited to the above-mentioned problems, and may be expanded in various ways without deviating from the idea and scope of the present invention.

### Technical Solution

In accordance with one aspect of the present invention, provided is a light-emitting device including nanoholes, the light-emitting device including a first conductive semiconductor layer; an active layer formed on the first conductive semiconductor layer; a second conductive semiconductor layer formed on the active layer; and nanoholes coated with nanoparticles that cause surface plasmon resonance, wherein the nanoholes are formed to penetrate the second conductive semiconductor layer and the active layer.

In one embodiment, the nanoholes may be formed through a process of forming an ohmic metal on the second conductive semiconductor layer, a process of forming holes penetrating the active layer by vertically etching the ohmic metal, the second conductive semiconductor layer, and the active layer, and a process of coating an inside of the holes with the nanoparticles.

In one embodiment, the nanoholes may be coated with the nanoparticles using at least one of a drop casting process, a spin coating process, an electrophoresis process, and a dewetting process.

In one embodiment, the active layer may emit red light with a wavelength of 620 nm to 680 nm, and the nanoparticles may include Au having a first shape to cause surface plasmon resonance for the wavelength of the red light.

In one embodiment, the nanoparticles may be at least one of core nanoparticles having a core structure and core-shell nanoparticles having a core-shell structure.

In one embodiment, the nanoparticles may include at least one of palladium (Pd), aluminum (Al), silver (Ag), platinum (Pt), copper (Cu), gold (Au), chromium (Cr), and rhodium (Rh).

In one embodiment, the nanoholes may include an insulating film disposed between the nanoparticles and the active layer. The nanoparticles may use the insulating film as a boundary to cause surface plasmon resonance with the active layer.

In one embodiment, the insulating film may include at least one of SiO₂, TiO₂, ZrO₂, and Al₂O₃.

In one embodiment, the nanoholes may have a diameter of 100 nm to 5 μm.

In one embodiment, the nanoholes may have a center-to-center spacing of 100 nm to 10 μm.

In accordance with another aspect of the present invention, provided is a method of manufacturing a light-emitting device including nanoholes, the method including a step of forming an LED and an ohmic metal; a step of performing a photolithography process; a step of forming nanoholes; a step of depositing a first insulating film; a step of removing PR; a step of coating with nanoparticles; a step of depositing a second insulating film; a step of exposing a p-ohmic metal; a step of exposing n-GaN; and a step of forming metal pads, wherein the LED includes a first conductive semiconductor layer, an active layer, and a second conductive semiconductor layer, and the nanoholes are formed to penetrate the second conductive semiconductor layer and the active layer.

### Advantageous Effects

A light-emitting device including nanoholes according to embodiments of the present invention can include nanoholes coated with nanoparticles and formed deep enough to penetrate an active layer. Since the nanoparticles are semi-permanently coated in close proximity to the active layer through the nanoholes, the effect of surface plasmon resonance can be increased in the light-emitting device including the nanoholes.

Accordingly, according to the light-emitting device including nanoholes and a method of manufacturing the light-emitting device including nanoholes according to embodiments of the present invention, the luminous efficiency of the light-emitting device can be maximized.

However, the effects of the present invention are not limited to the effects described above, and can be expanded in various ways without departing from the idea and scope of the present invention.

### DESCRIPTION OF DRAWINGS

FIG. 1 is a cross-sectional view showing the laminated structure of the light-emitting device including nanoholes according to embodiments of the present invention.

FIG. 2 is a perspective view showing the laminated structure of the light-emitting device including nanoholes of FIG. 1.

FIG. 3 is an enlarged view showing the nanoholes of the light-emitting device including nanoholes.

FIG. 4 is an enlarged view showing nanoparticles coated on the nanoholes.

FIG. 5 is an optical image showing an example of nanoparticles.

FIG. 6 is a flowchart showing a method of manufacturing the light-emitting device including nanoholes of FIG. 1.

FIG. 7 includes diagrams showing a process of manufacturing the light-emitting device including nanoholes of FIG. 1.

FIG. 8 is a diagram showing a case where the front surface of the light-emitting device including nanoholes according to embodiments of the present invention emits light.

FIG. 9 is a diagram showing a case where the back surface of the light-emitting device including nanoholes according to embodiments of the present invention emits light.

### BEST MODE

Specific structural and functional descriptions of embodiments according to the concept of the present invention disclosed herein are merely illustrative for the purpose of explaining the embodiments according to the concept of the present invention. Furthermore, the embodiments according to the concept of the present invention can be implemented in various forms and the present invention is not limited to the embodiments described herein.

The embodiments according to the concept of the present invention may be implemented in various forms as various modifications may be made. The embodiments will be described in detail herein with reference to the drawings. However, it should be understood that the present invention is not limited to the embodiments according to the concept of the present invention, but includes changes, equivalents, or alternatives falling within the spirit and scope of the present invention.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the teachings of the present invention.

It should be understood that when an element is referred to as being “connected to” or “coupled to” another element, the element may be directly connected or coupled to the other element or intervening elements may be present. In contrast, when an element is referred to as being “directly connected to” or “directly coupled to” another element, there are no intervening elements present. Other words used to describe the relationship between elements or layers should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

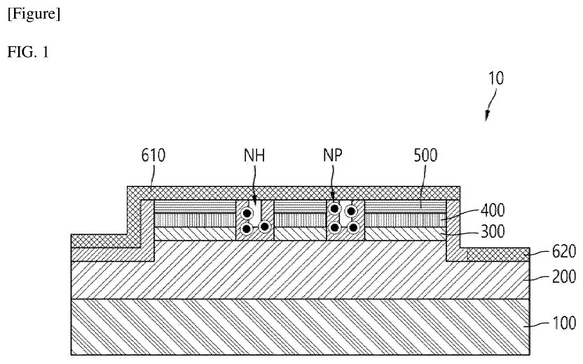

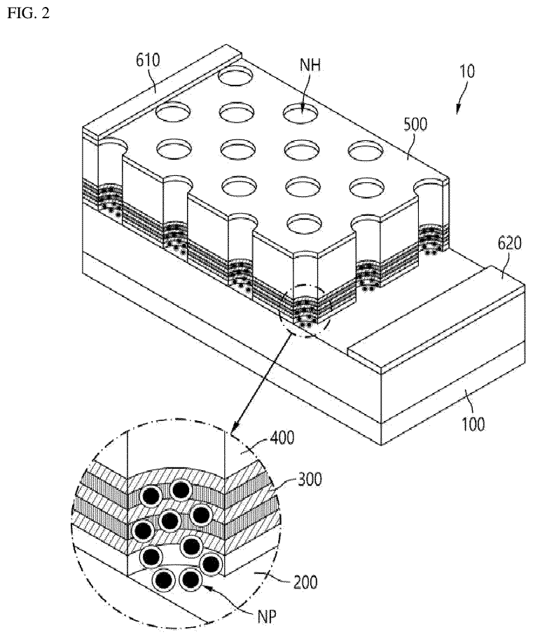

FIG. 1 is a cross-sectional view showing the laminated structure of the light-emitting device including nanoholes according to embodiments of the present invention, and FIG. 2 is a perspective view showing the laminated structure of the light-emitting device including nanoholes of FIG. 1.

Referring to FIGS. 1 and 2, the light-emitting device including nanoholes may include a first conductive semiconductor layer 200, an active layer 300, a second conductive semiconductor layer 400, and nanoholes (NH).

In addition, the light-emitting device including nanoholes may further include a substrate 100 disposed on the lower portion of the first conductive semiconductor layer 200, an ohmic metal 500 disposed on the upper portion of the second conductive semiconductor layer 400, and metal pads 600.

Specifically, the light-emitting device including nanoholes may include the first conductive semiconductor layer 200 formed on the substrate 100, the active layer 300 formed on the first conductive semiconductor layer 200, the second conductive semiconductor layer 400 formed on the active layer 300, and the nanoholes (NH) coated with nanoparticles (NP) that cause surface plasmon resonance.

The substrate 100 may be made of a material capable of epitaxially laminating a semiconductor such as GaN. For example, the substrate 100 may include at least one of sapphire, silicon carbide (SiC), gallium arsenide (GaAs), gallium nitride (GaN), silicon (Si), gallium phosphide (GaP), indium phosphide (InP), zinc oxide (ZnO), MgAl₂O₄ MgO, LiAlO₂, and LiGaO₂.

The first conductive semiconductor layer 200 and the second conductive semiconductor layer 400 may be at least one of an n-type semiconductor layer and a p-type semiconductor layer, respectively.

For example, the first conductive semiconductor layer 200 and the second conductive semiconductor layer 400 may be formed of a nitride semiconductor.

The first conductive semiconductor layer 200 and the second conductive semiconductor layer 400 may be composed of materials such as GaN, AlGaN, and InGaN.

For example, Si, Ge, Se, Te, and the like may be used as n-type impurities in the first conductive semiconductor layer 200.

For example, Mg, Zn, Be, and the like may be used as p-type impurities in the second conductive semiconductor layer 400.

The first conductive semiconductor layer 200 and the second conductive semiconductor layer 400 may be formed using at least one of the MOCVD process, the MBE process, and the HVPE process.

The active layer 300 may emit light with a predetermined energy by recombination of electrons and holes.

For example, the active layer 300 may be a layer made of a single material such as InGaN.

For example, the active layer 300 may be formed in a multiple quantum well (MQW) structure in which quantum barrier layers and quantum well layers are alternately arranged.

The active layer 300 may include at least one of GaN, AlN, InN, InGaN, AlGaN, and InAlGaN.

For example, when the active layer 300 has a multiple quantum well (MQW) structure, the quantum well layer may be composed of a material with a small energy band gap among GaN, AlN, InN, InGaN, AlGaN, and InAlGaN, and the quantum barrier layer may be composed of a material with a large energy band gap among GaN, AlN, InN, InGaN, AlGaN, and InAlGaN.

The first conductive semiconductor layer 200, the active layer 300, and the second conductive semiconductor layer 400 may form one unit LED structure.

The ohmic metal 500 may be formed on the second conductive semiconductor layer 400. The ohmic metal 500 may be an electrode for applying voltage to the second conductive semiconductor layer 400. For example, the ohmic metal 500 may be a p-ohmic metal.

The nanoholes (NH) may be formed in a direction perpendicular to the surface on which the first conductive semiconductor layer 200, the active layer 300, and the second conductive semiconductor layer 400 are laminated. The nanoholes (NH) may be formed repeatedly in a certain arrangement in the unit LED structure in the vertical direction.

The nanoholes (NH) may be formed to penetrate the second conductive semiconductor layer 400 and the active layer 300. For example, the nanoholes (NH) may be formed to penetrate the active layer 300 and may be formed up to a portion of the first conductive semiconductor layer 200.

The nanoholes (NH) may be coated with the nanoparticles (NP), which cause surface plasmon resonance. For example, the nanoholes (NH) may include an insulating film disposed between the nanoparticles (NP) and the active layer 300. The nanoparticles (NP) may use the insulating film as a boundary to cause surface plasmon resonance with the active layer 300.

Specifically, the nanoholes (NH) may be formed through a process of forming the ohmic metal 500 on the second conductive semiconductor layer 400, a process of forming a hole penetrating the active layer 300 by vertically etching the ohmic metal 500, the second conductive semiconductor layer 400, and the active layer 300, and a process of coating the inside of the hole with the nanoparticles (NP).

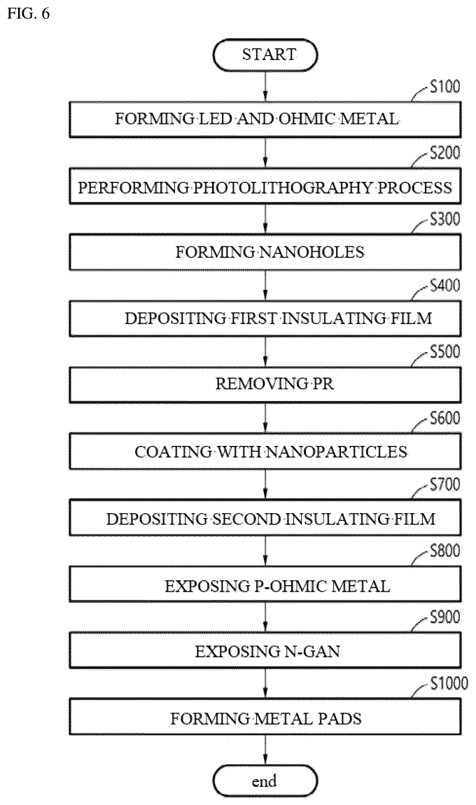

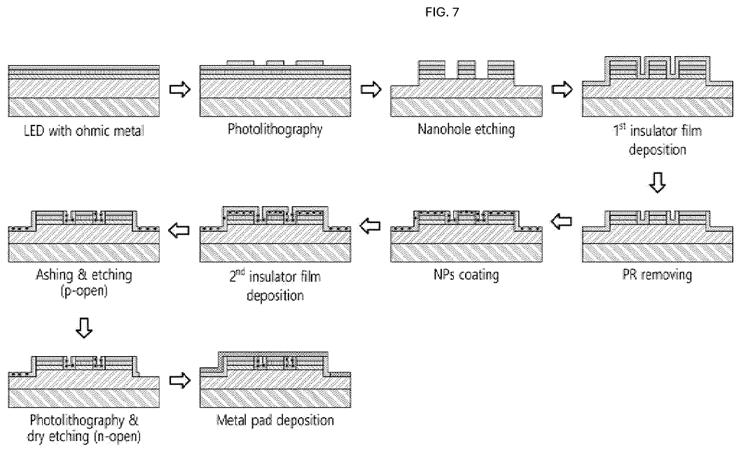

In addition, the specific manufacturing process of the light-emitting device including nanoholes of the present invention is described in detail later with reference to FIGS. 6 and 7.

As shown in the enlarged view of FIG. 2, through the nanoholes (NH), areas close to the active layer 300 may be semi-permanently coated with the nanoparticles (NP). Accordingly, the surface plasmon resonance effect by the nanoparticles (NP) may be maximized in the light-emitting device.

The metal pads 600 may be formed to apply electricity to the unit LED structure through wiring, etc. The metal pads 600 may include a p-type metal pad 610 and an n-type metal pad 620.

For example, the p-type metal pad 610 may be electrically connected to the ohmic metal 500. For example, the n-type metal pad 620 may be electrically connected to the first conductive semiconductor layer 200.

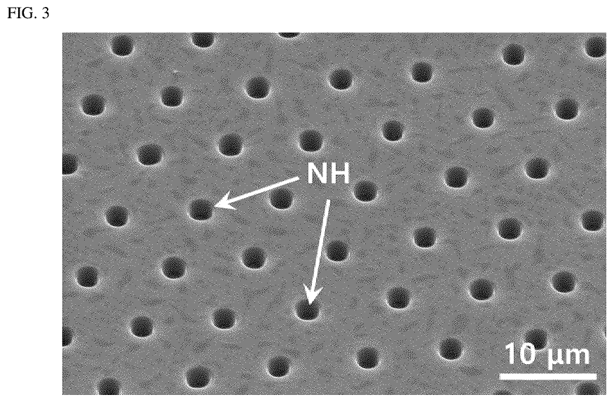

FIG. 3 is an enlarged view showing the nanoholes (NH) of the light-emitting device including nanoholes.

Referring to FIG. 3, the nanoholes (NH) may be formed in a direction perpendicular to the surface on which the first conductive semiconductor layer 200, the active layer 300, and the second conductive semiconductor layer 400 are laminated.

As shown in FIG. 3, the cross-section of the nanoholes (NH) may be circular. For example, the diameter of the nanoholes (NH) may be 100 nm to 5 μm.

In addition, the shape of the nanoholes (NH) according to embodiments of the present invention is not limited to the circular shape. For example, the nanoholes (NH) may have various shapes such as triangles, squares, and hexagons.

In one embodiment, the nanoholes (NH) may have a certain arrangement. The nanoholes (NH) may be formed periodically and repeatedly. For example, the center-to-center spacing of the nanoholes (NH) may be 100 nm to 10 μm.

The nanoholes (NH) may include an insulating film disposed between the nanoparticles (NP) and the active layer 300. The nanoparticles (NP) may use the insulating film as a boundary to cause surface plasmon resonance with the active layer 300.

The insulating film may function to form an appropriate gap between the active layer 300 and the nanoparticles (NP). For example, the insulating film may have a thickness of 1 nm to 150 nm.

In one embodiment, the insulating film may include at least one of SiO₂, TiO₂, ZrO₂, and Al₂O₃.

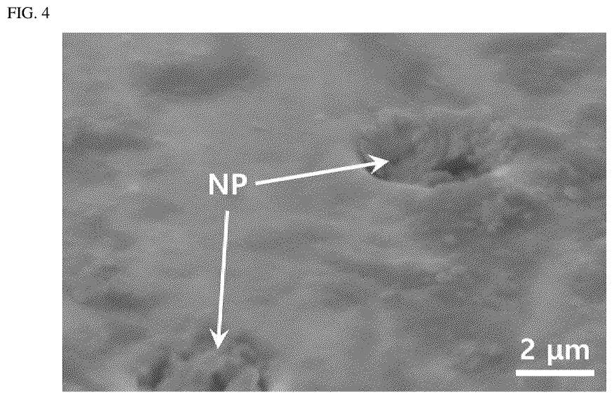

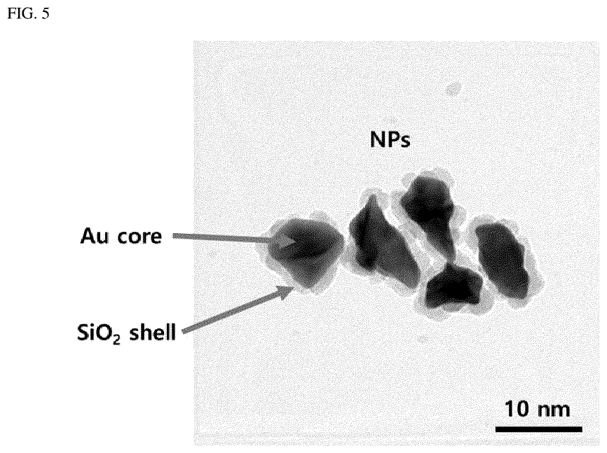

FIG. 4 is an enlarged view showing the nanoparticles (NP) coated on the nanoholes (NH), and FIG. 5 is an optical image showing an example of the nanoparticles (NP).

Referring to FIG. 4, the inside of the nanoholes (NH) may be semi-permanently coated with the nanoparticles (NP). When the nanoholes (NH) are coated with the nanoparticles (NP), the nanoparticles (NP) may cause surface plasmon resonance.

The nanoparticles (NP) are materials suitable for using the surface plasmon phenomenon, and may be composed of metals that easily emit electrons by external stimulation and have a negative dielectric constant.

For example, the nanoparticles (NP) may include at least one of palladium (Pd), aluminum (Al), silver (Ag), platinum (Pt), copper (Cu), gold (Au), chromium (Cr), rhodium (Rh), nickel (Ni), and titanium (Ti).

Through the nanoholes (NH) formed to penetrate the active layer 300, areas adjacent to the active layer 300 may be semi-permanently coated with the nanoparticles (NP).

Specifically, the surface of the active layer 300 may be coated with the nanoparticles (NP) with the insulating film as a boundary so that the distance between the nanoparticles (NP) and the active layer 300 is 1 nm to 150 nm. That is, the nanoparticles (NP) may use the insulating film as a boundary to cause surface plasmon resonance with the active layer.

For example, the nanoparticles (NP) may be core nanoparticles (NP) with a core structure. For example, the nanoparticles (NP) may be core-shell nanoparticles (NP) with a core-shell structure.

The inside of the nanoholes (NH) may be coated with the nanoparticles (NP) using at least one of a drop casting process, a spin coating process, an electrophoresis process, and a dewetting process.

In one embodiment, the unit LED structure may be a red LED that emits red light. For example, the active layer 300 may emit red light with a wavelength of 620 nm to 680 nm.

In a red LED, the nanoparticles (NPs) may include Au, which has a first shape to cause surface plasmon resonance for the wavelength of red light.

As shown in FIG. 5, in a red LED, the nanoparticles (NP) may be core-shell nanoparticles (NP) with a core-shell structure. For example, the nanoparticles (NP) may consist of an Au core and an SiO₂ shell.

To cause surface plasmon resonance for the wavelength of red light, the nanoparticles (NPs) may have a first shape optimized for red LEDs. For example, the first shape may be a pointed shape, a star shape, an angled shape, or the like.

In addition, the shape of the nanoparticles (NP) of the present invention is not limited to the first shape. For example, the unit LED structure of the present invention may emit green light, blue light, and infrared light in addition to red light.

Accordingly, the shape of the nanoparticles (NP) of the present invention is not limited to the first shape, and the nanoparticles (NP) may have an optimal shape to cause surface plasmon resonance for the wavelength of a target light source. For example, the nanoparticles (NP) may have various shapes, including spheres, cuboids, and octahedrons.

FIG. 6 is a flowchart showing a method of manufacturing the light-emitting device including nanoholes of FIG. 1, and FIG. 7 includes diagrams showing a process of manufacturing the light-emitting device including nanoholes of FIG. 1.

Referring to FIGS. 6 and 7, the light-emitting device including nanoholes according to the present invention may be manufactured through step S100 of forming an LED and the ohmic metal 500, step S200 of performing a photolithography process, step S300 of depositing the nanoholes (NH), step S400 of depositing a first insulating film, step S500 of removing PR, step S600 of coating with the nanoparticles (NP), step S700 of depositing a second insulating film, step S800 of exposing a p-ohmic metal, step S900 of exposing n-GaN, and step S1000 of forming the metal pads 600.

In one embodiment, the method of manufacturing a light-emitting device including nanoholes may include step S100 of forming an LED and the ohmic metal 500. The LED may include the first conductive semiconductor layer 200, the active layer 300, and the second conductive semiconductor layer 400.

For example, according to the method of manufacturing a light-emitting device, the first conductive semiconductor layer 200 may be formed on the substrate 100, the active layer 300 may be formed on the first conductive semiconductor layer 200, and the second conductive semiconductor layer 400 may be formed on the active layer 300.

The substrate 100 may be made of a material capable of epitaxially laminating a semiconductor such as GaN. For example, the substrate 100 may include at least one of sapphire, silicon carbide (SiC), gallium arsenide (GaAs), gallium nitride (GaN), silicon (Si), gallium phosphide (GaP), indium phosphide (InP), zinc oxide (ZnO), MgAl₂O₄, MgO, LiAlO₂, and LiGaO₂.

The first conductive semiconductor layer 200 and the second conductive semiconductor layer 400 may be formed as a nitride semiconductor. For example, the first conductive semiconductor layer 200 and the second conductive semiconductor layer 400 may be formed of a material such as GaN, AlGaN, and InGaN.

The active layer 300 may emit light with a predetermined energy by recombination of electrons and holes. For example, the active layer 300 may be formed in a multiple quantum well (MQW) structure in which quantum barrier layers and quantum well layers are alternately arranged.

For example, a quantum well layer may be formed of a material with a small energy band gap among GaN, AlN, InN, InGaN, AlGaN, and InAlGaN, and a quantum barrier layer may be formed of a material with a large energy band gap among GaN, AlN, InN, InGaN, AlGaN, and InAlGaN.

According to the method of manufacturing a light-emitting device, the ohmic metal 500 may be further formed on the second conductive semiconductor layer 400. The ohmic metal 500 may be an electrode for applying voltage to the second conductive semiconductor layer 400. For example, the ohmic metal 500 may be a p-ohmic metal.

In one embodiment, the method of manufacturing a light-emitting device including nanoholes may include step S200 of performing a photolithography process.

In the photolithography process, a mask metal may be deposited on the ohmic metal 500 on top of the LED structure, and the mask metal may be selectively patterned.

For example, the mask metal may be patterned using electron-beam lithography, focused ion beam (FIB) lithography, nano-imprint, a mask formation method using SiO₂ nanoparticles, a self-assembled metal mask, or the like.

In one embodiment, the method of manufacturing a light-emitting device including nanoholes may include step S300 of depositing the nanoholes (NH).

The nanoholes (NH) may be formed in a direction perpendicular to the surface on which the first conductive semiconductor layer 200, the active layer 300, and the second conductive semiconductor layer 400 are laminated. The nanoholes (NH) may be formed repeatedly in a certain arrangement in the unit LED structure in the vertical direction.

In the step of forming the nanoholes (NH), a selective etching process using nano-patterning technology may be used to selectively remove the unit LED structure and the ohmic metal 500. For example, in the step of forming the nanoholes (NH), selective etching may be performed using dry etching.

Specifically, in the step of forming the nanoholes (NH), selective etching may be performed using reactive ion etching (RIE), inductively coupled plasma reactive ion etching (ICP-RIE), chemically assisted ion beam etching (CAIBE), or the like.

For example, when using inductively coupled plasma reactive ion etching (ICP-RIE), by appropriately adjusting process parameters such as selectivity and etch rate, the unit LED structure and the ohmic metal 500 may be etched.

The nanoholes (NH) may be formed to penetrate the second conductive semiconductor layer 400 and the active layer 300. For example, the nanoholes (NH) may penetrate the active layer 300 and form up to a portion of the first conductive semiconductor layer 200.

In one embodiment, the method of manufacturing a light-emitting device including nanoholes may including step S400 of depositing a first insulating film and step S500 of removing PR.

The nanoholes (NH) may include a first insulating film disposed between the nanoparticles (NP) and the active layer 300.

The first insulating film may function to form an appropriate distance between the active layer 300 and the nanoparticles (NP). For example, the first insulating film may have a thickness of 1 nm to 150 nm.

The first insulating film may include at least one of SiO₂, TiO₂, ZrO₂, and Al₂O₃.

After depositing the first insulating film, the process of removing PR may be performed. For example, PR may be removed using acetone and isopropyl alcohol (IPA). As another example, PR may be removed through an etching process.

In one embodiment, the method of manufacturing a light-emitting device including nanoholes may include step S600 of coating with the nanoparticles (NP).

The nanoholes (NH) may be coated with the nanoparticles (NP) that cause surface plasmon resonance. The nanoparticles (NP) may use the first insulating film as a boundary to cause surface plasmon resonance with the active layer 300.

The nanoparticles (NP) are materials suitable for using the surface plasmon phenomenon, and may be composed of metals that easily emit electrons by external stimulation and have a negative dielectric constant.

For example, the nanoparticles (NP) may include at least one of palladium (Pd), aluminum (Al), silver (Ag), platinum (Pt), copper (Cu), gold (Au), chromium (Cr), rhodium (Rh), nickel (Ni), and titanium (Ti).

For example, the nanoparticles (NP) may be core nanoparticles (NP) having a core structure. For example, the nanoparticles (NP) may be core-shell nanoparticles (NP) having a core-shell structure.

The inside of the nanoholes (NH) may be coated with the nanoparticles (NP) using at least one of a drop casting process, a spin coating process, an electrophoresis process, and a dewetting process.

In this way, when areas close to the active layer 300 are coated with the nanoparticles (NP) through the nanoholes (NH), the surface plasmon resonance effect may be maximized in the light-emitting device.

In one embodiment, the method of manufacturing a light-emitting device including nanoholes may include step S700 of depositing a second insulating film.

The second insulating film may function to protect the nanoparticles (NP) so that the inside of the nanoholes (NH) is semi-permanently coated with the nanoparticles (NP).

Like the first insulating film, the second insulating film may include at least one of SiO₂, TiO₂, ZrO₂, and Al₂O₃.

In one embodiment, the method of manufacturing a light-emitting device including nanoholes may include step S800 of exposing a p-ohmic metal, step S900 of exposing n-GaN, and step S1000 of forming the metal pads 600.

In the step of exposing a p-ohmic metal, by ashing and etching the second insulating film formed on the upper layer of the ohmic metal 500 on the second conductive semiconductor layer 400, the p-ohmic metal may be exposed.

In the step of exposing n-GaN, by removing the second insulating film formed on the upper portion of the first conductive semiconductor layer 200 using a photolithography process and a dry etching process, n-GaN may be removed.

In the step of forming the metal pads 600, the p-type metal pad 610 and the n-type metal pad 620 may be formed to apply electricity to the unit LED structure through wiring, etc.

For example, the p-type metal pad 610 may be electrically connected to the p-ohmic metal. For example, the n-type metal pad 620 may be electrically connected to the first conductive semiconductor layer 200.

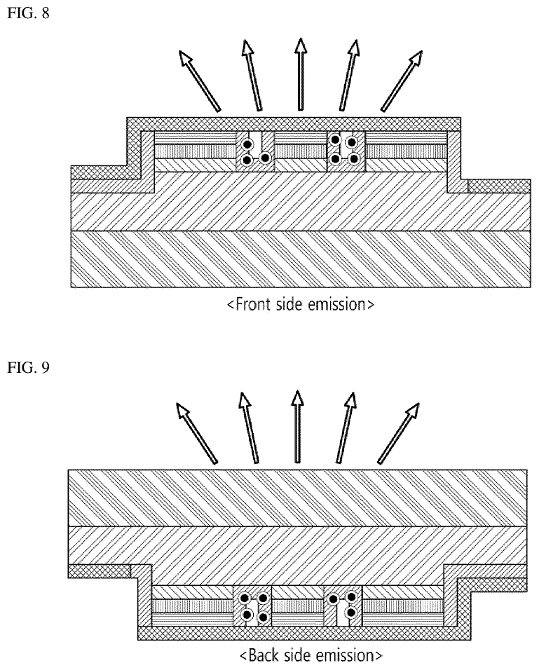

FIG. 8 is a diagram showing a case where the front surface of the light-emitting device including nanoholes according to embodiments of the present invention emits light.

Referring to FIG. 8, light output from the active layer 300 may pass through the ohmic metal 500. For example, the ohmic metal 500 may be composed of a transparent metal. Accordingly, the front surface of the light-emitting device including nanoholes may emit light.

In particular, when the front surface of the light-emitting device including nanoholes emits light, since the nanoparticles (NP) are continuously fixed near the active layer 300 through the nanoholes (NH), internal quantum efficiency may be increased.

FIG. 9 is a diagram showing a case where the back surface of the light-emitting device including nanoholes according to embodiments of the present invention emits light.

Referring to FIG. 9, light output from the active layer 300 may be reflected from the ohmic metal 500. For example, the ohmic metal 500 may be composed of a metal that may reflect light. Accordingly, the back surface of the light-emitting device including nanoholes may emit light.

In addition, when the back surface of the light-emitting device including nanoholes emits light, since the nanoparticles (NP) are continuously fixed near the active layer 300 through the nanoholes (NH), internal quantum efficiency may be increased.

That is, since the nanoparticles (NP) are semi-permanently coated in close proximity to the active layer 300 through the nanoholes (NH), the effect of surface plasmon resonance may be increased in the light-emitting device including the nanoholes.

Accordingly, according to the light-emitting device including nanoholes and the method of manufacturing the light-emitting device including nanoholes according to embodiments of the present invention, the luminous efficiency of the light-emitting device may be maximized.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A light-emitting device comprising nanoholes, comprising:
a first conductive semiconductor layer;
an active layer formed on the first conductive semiconductor layer;
a second conductive semiconductor layer formed on the active layer; and
nanoholes coated with nanoparticles that cause surface plasmon resonance,
wherein the nanoholes are formed to penetrate the second conductive semiconductor layer and the active layer.

2. The light-emitting device according to claim 1, wherein the nanoholes are formed through a process of forming an ohmic metal on the second conductive semiconductor layer, a process of forming holes penetrating the active layer by vertically etching the ohmic metal, the second conductive semiconductor layer, and the active layer, and a process of coating an inside of the holes with the nanoparticles.

3. The light-emitting device according to claim 1, wherein the nanoholes are coated with the nanoparticles using at least one of a drop casting process, a spin coating process, an electrophoresis process, and a dewetting process.

4. The light-emitting device according to claim 1, wherein the active layer emits red light with a wavelength of 620 nm to 680 nm, and the nanoparticles comprise Au having a first shape to cause surface plasmon resonance for the wavelength of the red light.

5. The light-emitting device according to claim 1, wherein the nanoparticles are at least one of core nanoparticles having a core structure and core-shell nanoparticles having a core-shell structure.

6. The light-emitting device according to claim 1, wherein the nanoparticles comprise at least one of palladium (Pd), aluminum (Al), silver (Ag), platinum (Pt), copper (Cu), gold (Au), chromium (Cr), and rhodium (Rh).

7. The light-emitting device according to claim 1, wherein the nanoholes comprise an insulating film disposed between the nanoparticles and the active layer, and the nanoparticles use the insulating film as a boundary to cause surface plasmon resonance with the active layer.

8. The light-emitting device according to claim 7, wherein the insulating film comprises at least one of SiO₂, TiO₂, ZrO₂, and Al₂O₃.

9. The light-emitting device according to claim 1, wherein the nanoholes have a diameter of 100 nm to 5 μm.

10. The light-emitting device according to claim 1, wherein the nanoholes have a center-to-center spacing of 100 nm to 10 μm.

11. A method of manufacturing a light-emitting device comprising nanoholes, comprising:
a step of forming an LED and an ohmic metal;
a step of performing a photolithography process;
a step of forming nanoholes;
a step of depositing a first insulating film;
a step of removing PR;
a step of coating with nanoparticles;
a step of depositing a second insulating film;
a step of exposing a p-ohmic metal;
a step of exposing n-GaN; and
a step of forming metal pads,
wherein the LED comprises a first conductive semiconductor layer, an active layer, and a second conductive semiconductor layer, and
the nanoholes are formed to penetrate the second conductive semiconductor layer and the active layer.
